(19) United States
(12) Patent Application Publication
(10) Pub. No.: US 2025/0113520 A1
(43) Pub. Date: Apr. 3, 2025

(54) TRANSFER OF A 2D MATERIAL TO A TARGET SUBSTRATE

(71) Applicant: Intel Corporation, Santa Clara, CA (US)

(72) Inventors: Andrey Vyatskikh, Hillsboro, OR (US); Paul Fischer, Portland, OR (US); Paul Nordeen, Portland, OR (US); Kevin O'Brien, Portland, OR (US); Chelsey Dorow, Portland, OR (US); Carl H. Naylor, Portland, OR (US); Uygar Avci, Portland, OR (US)

(73) Assignee: Intel Corporation, Santa Clara, CA (US)

(21) Appl. No.: 18/375,051

(22) Filed: Sep. 29, 2023

(51) Int. Cl. H01L 29/775; H01L 21/762

(52) U.S. Cl. CPC H10D 30/43; H01L 21/76259

(57) ABSTRACT

Techniques and mechanisms for a transition metal dichalcogenide (TMD) material to be grown on one structure, and then transferred to a different structure. In an embodiment, one or more monolayers of a TMD material are grown on a workpiece comprising a substrate, a growth layer, and a release layer. A material of the substrate is transparent to a wavelength of a laser light, wherein the release layer is opaque to said wavelength. The resulting material stack is then coupled to a target structure, after which a laser ablation is performed to remove some or all of the release layer from between the substrate and the growth layer. The ablation enables the substrate to be separated from the one or more monolayers. In an embodiment, a residue on a surface of the one or more TMD monolayers is an artefact of the layer transfer process.

### BACKGROUND

### 1. Technical Field

This disclosure generally relates to the fabrication of integrated circuitry and more particularly, but not exclusively, to the transferring of a two-dimensional (2D) material to a target structure.

### 2. Background Art

Demand for integrated circuits (ICs) in portable electronic applications has motivated greater levels of semiconductor device integration. Many advanced semiconductor devices in development leverage non-silicon semiconductor materials. One class of those materials is the transition metal dichalcogenide (TMD or TMDC). Similar to graphene, TMDs display semiconductor properties as a unit cell of MX2, where M is a transition metal atom (e.g., Mo, W) and X is a chalcogen atom (S, Se, or Te). TMD materials have been of significant interest in highly-scaled integrated circuitry (IC), in part because of the thin active layers possible. TMD-channeled transistors therefore have excellent short channel properties. It has also been shown that many TMD materials have good electron and hole mobility, making them interesting for complementary short channel devices (e.g., Lg<20 nm).

Recent TMD-based transistor designs are facilitated by (for example, implemented with) one or more TMD structures each being implemented as a respective “2D material”—i.e., as a material layer, at least a substantial portion of which is not more than one molecule in thickness. However, implementation of 2D materials in field effect transistors (FETs) has proven to be a challenge, and has resulted in various complications in the formation of channels and adjoining structures of a transistor. As successive generations of transistor designs continue to decrease in scale, there is expected to be an increasing premium placed on improvements to the fabrication of a 2D material and structures proximate thereto.

### BRIEF DESCRIPTION OF THE DRAWINGS

The various embodiments of the present invention are illustrated by way of example, and not by way of limitation, in the figures of the accompanying drawings and in which:

FIG. 1 shows a flow diagram illustrating features of a method to transfer a two-dimensional (2D) material to a target substrate according to an embodiment.

FIGS. 2A-2G show cross-sectional diagrams each illustrating a respective stage of processing to provide a 2D material on a target substrate according to an embodiment.

FIGS. 3A-3D show cross-sectional diagrams each illustrating a respective stage of processing to provide multiple 2D material layers on a target substrate according to an embodiment.

FIG. 4 shows a cross-sectional side view diagram illustrating features of an integrated circuit (IC) die which comprises an artefact of a layer transfer process according to an embodiment.

FIG. 5 is a cross-sectional side view of an IC structure, in accordance with some embodiments.

FIG. 6 is a functional block diagram illustrating a system which comprises a packaged IC die that includes transistor structures according to one embodiment.

FIG. 7 is a functional block diagram which illustrates an electronic computing device in accordance with some embodiments.

### DETAILED DESCRIPTION

Embodiments discussed herein variously provide techniques and mechanisms for one or more monolayers of a transition metal dichalcogenide (TMD) material to be grown on one structure and then transferred to a different structure. Such TMD monolayers are suitable as 2D materials that, for example, facilitate the fabrication of nanowires, nanoribbons and/or other relatively small thickness channel structures of a transistor.

However, such fabrication has to-date been sensitive to material damage caused during the transfer of such one or more TMD monolayers. In conventional fabrication techniques, a layer of a 2D material is subjected to stress caused by a mechanical cleaving of the layer from a substrate on which the 2D material is grown. The layer is then subjected to additional stress when a carrier substrate is mechanical cleaved, peeled or otherwise removed off of an opposite side of the 2D layer.

To avoid or otherwise mitigate such stress, some embodiments variously provide a release layer between a support substrate and a layer (“growth layer” herein) on which a 2D material is to be formed. For example, an ablation of the release layer accommodates efficient separation of the support substrate (or “growth substrate” herein) from one or more monolayers of a 2D material.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including an artefact of a layer transfer process.

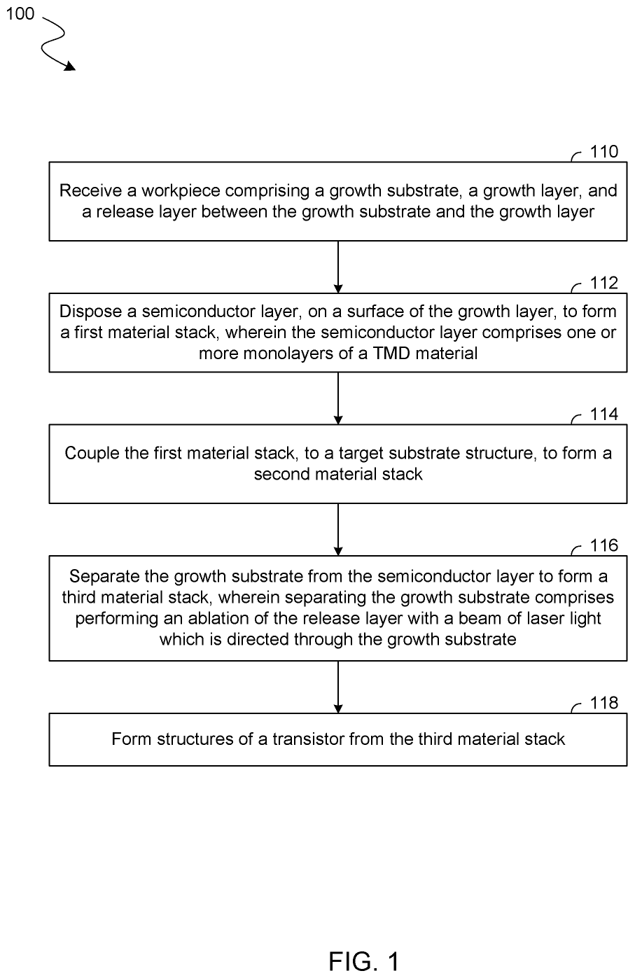

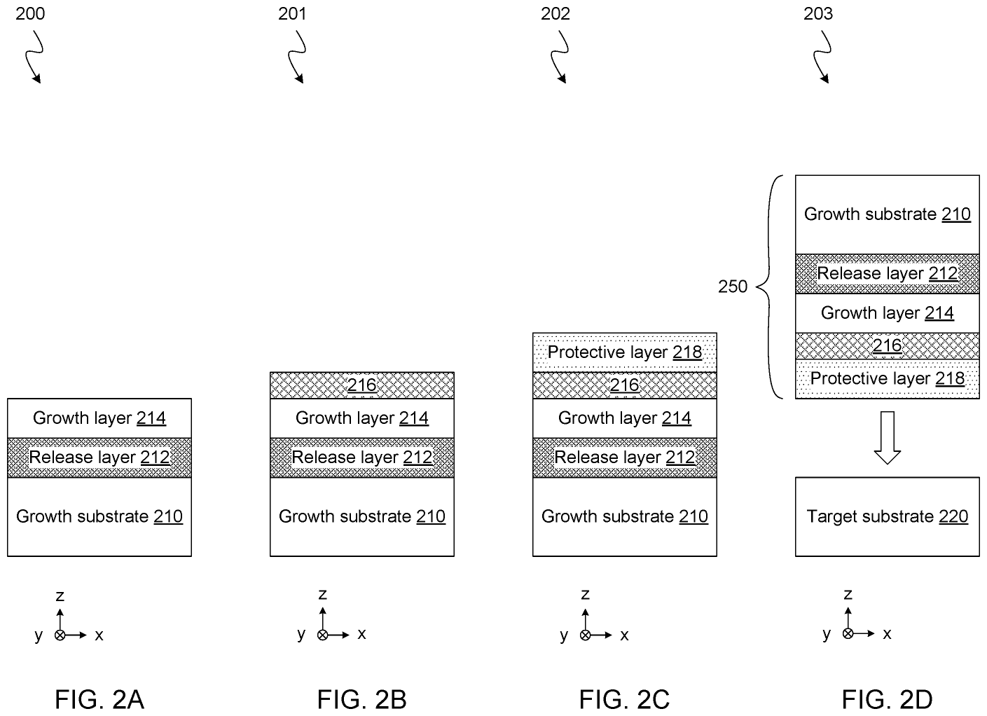

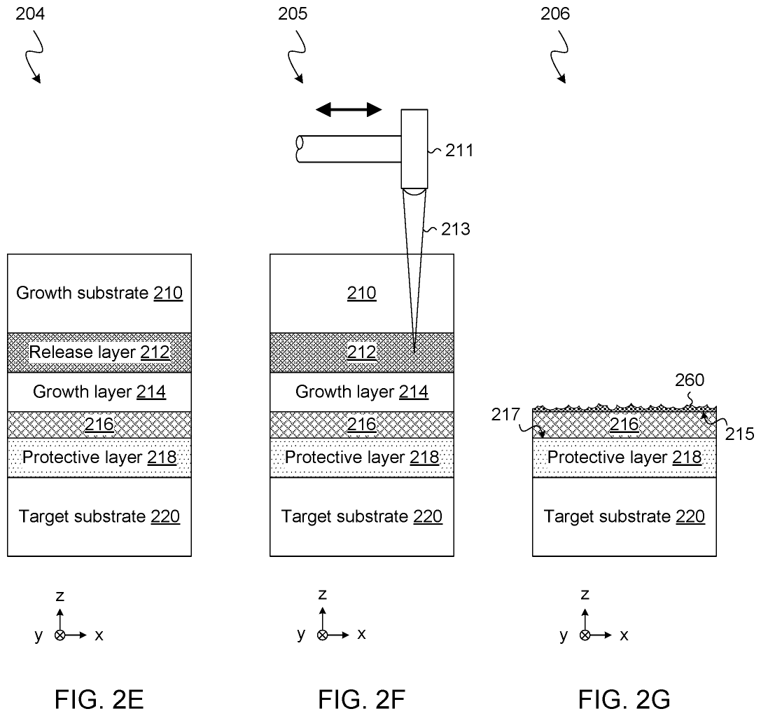

FIG. 1 shows a method 100 for transferring a 2D material to a target substrate according to an embodiment. Method 100 illustrates one example of an embodiment wherein one or more monolayers of a TMD material are transferred to a target structure (referred to herein as a “target substrate structure”), wherein a laser ablation process mitigates damage to the one or more monolayers during a separation of structures which are used for said transfer. To illustrate certain features of various embodiments, operations of method 100 are described herein with reference to structures which are shown in FIGS. 2A-2G. However, such operations are performed to provide and/or use any of various alternative additional or alternative structures, in other embodiments.

As shown in FIG. 1, method 100 comprises (at 110) receiving a workpiece comprising a growth substrate, a growth layer, and a release layer between the growth substrate and the growth layer. For example, FIGS. 2A-2G show various cross-sectional side views of structures each during a respective one of multiple stages 200 through 206 of processing for providing a 2D material on a target substrate according to an embodiment. Structures of FIGS. 2A-2G are shown with reference to an xyz Cartesian coordinate system. Unless otherwise indicated, “length” refers herein to a dimension along the x-axis of the coordinate system, wherein “width” and “height” refer to dimensions along the y-axis and along the z-axis (respectively) of the coordinate system.

Referring now to the stage 200 shown in FIG. 2A, a workpiece comprises a growth substrate 210, a growth layer 214, and a release layer 212 which is between growth substrate 210 and growth layer 214. The growth substrate 210 illustrates any of various structures which are suitable to provide structural support for the growth of a 2D material which is to be subsequently transferred to a target substrate. The growth substrate 210 comprises a bulk material which is transparent to a laser light which is to be subsequently used for separation of growth substrate 210 from the 2D material. In an embodiment, a wavelength of such a laser light is in an infrared (IR) band—e.g., in a range of 780 nanometers (nm) to 1 millimeter (mm). By way of illustration and not limitation, the growth substrate 210 comprises a silicon material, a sapphire, of any of various other IR transparent materials.

Growth layer 214 illustrates any of various material layers which are suitable to provide a site on which one or more monolayers of a TMD material are to be grown. For example, growth layer 214 comprises a crystalline structure which facilitates the growth of a TMD monolayer which has a particular corresponding crystalline structure. The material of growth layer 214 is the same as that of growth substrate 210, in some embodiments—e.g., wherein growth layer 214 comprise a silicon material or a sapphire material.

Release layer 212 illustrates any of various structures which are susceptible to laser ablation via a beam of laser light which is directed through growth substrate 210. In an embodiment, a material of the release layer 212 is absorbent of (e.g., opaque to) at least the range of wavelengths for the laser light which is subsequently to be directed through growth substrate 210. The release layer 212 includes one or more layers each of a respective material to accommodate the type of release or debonding technology used. For example, for IR laser debonding, the release layer 212 includes one or more layers of material(s) capable of absorbing and/or reflecting infrared (IR) electromagnetic radiation, such as a thin metal layer or multiple metal layers (e.g., aluminum (Al), tungsten (W), copper (Cu), titanium (Ti), titanium nitride (TiN), tantalum (Ta), tantalum nitride (TaN), or niobium nitride (NbN)). For UV laser debonding, the release layer 212 includes one or more layers of material(s) capable of absorbing ultraviolet (UV) electromagnetic radiation (e.g., organic polymers such as polyimides). In some embodiments, the release layer 212 may additionally or alternatively include one or more layers of dielectric materials to buffer laser ablation and thermal energy, control thin film interference or adhesion, and/or provide residual adhesion after other materials and/or layers in the release layers are weakened, removed, and/or ablated by a laser (e.g., silicon dioxide (SiO₂), silicon nitride (Si₃N₄), silicon oxynitride (SiON), silicon carbide (SiC), silicon carbon nitride (SiCN), silicon oxycarbon nitride (SiOCN), aluminum oxide (Al₂O₃), low-k dielectrics such as carbon-doped oxide (CDO) or porous silicon dioxide (SiO₂), titanium dioxide (TiO₂), tantalum oxide (Ta₂O₅)). Thus, in some embodiments, the release layer(s) may be made of one or more materials that include elements such as one of aluminum (Al), tungsten (W), copper (Cu), titanium (Ti), tantalum (Ta), niobium (Nb), silicon (Si), oxygen (O), nitrogen (N), hydrogen (H), or carbon (C), including, without limitation, any of the materials referenced above. In one such embodiment, release layer 212 comprises one of aluminum (Al), tungsten (W), copper (Cu), titanium (Ti), tantalum (Ta), niobium (Nb), or nitrogen (N). By way of illustration and not limitation, release layer 212 comprises any of various suitable IR absorbent metal nitrides including, but not limited to, titanium nitride (TiN), niobium nitride (NbN), tantalum nitride (TaN) or the like.

In an embodiment, a vertical (z-axis) thickness of release layer 212 is less than 1 mm—e.g., wherein the vertical thickness is less than 500 nm and, in some embodiments, less than 100 nm. In some embodiments, a vertical (z-axis) thickness of growth layer 214 facilitates a later removal of growth layer 214 with relatively low on the TMD material formed thereon. For example, a vertical thickness of growth layer 214 facilitates removal of substantially all of the growth layer 214 during a laser ablation process. Alternatively or in addition, the vertical thickness of growth layer 214 facilitates removal of substantially all of the growth layer 214 with a wet etch (or other suitable process) after said laser ablation. By way of illustration and not limitation, a vertical (z-axis) thickness of growth layer 214 is in a range of less than 100 nm—e.g., wherein the vertical thickness is less than 50 nm and, in some embodiments, less than 20 nm. However, such thickness dimensions of release layer 212 and growth layer 214 are merely illustrative, and not limiting on other embodiments.

Referring again to FIG. 1, method 100 further comprises (at 112) disposing a semiconductor layer, on a surface of the growth layer, to form a first material stack. The semiconductor layer comprises one or more monolayers of a transition metal dichalcogenide (TMD) material. For example, as shown in FIG. 2B, a semiconductor layer 216 is grown on growth layer 214 at stage 201, wherein semiconductor layer 216 comprises one or more monolayers of a TMD material. TMDs have the chemical formula MX2 where M is a transition metal and X is a chalcogen. A TMD monolayer comprises a middle layer of M atoms sandwiched between two layers of X atoms. TMD monolayers, which can also be referred to as 2D TMD layers, are typically less than 1 nanometer thick. The TMD monolayers disclosed in any of the embodiments described or referenced herein can comprise titanium, molybdenum, tungsten, platinum, erbium, lanthanum, rhodium, niobium, or another transition metal; with sulfur, selenium or tellurium as the chalcogen. That is, in some embodiments, the TMD monolayers described or referenced herein comprise one of molybdenum disulfide (MoS₂), molybdenum diselenide (MoSe₂), molybdenum ditelluride (MoTe₂), titanium disulfide (TiS₂), titanium diselenide (TiSe₂), titanium ditelluride (TiTe₂), tungsten disulfide (WS₂), tungsten diselenide (WSe₂), tungsten ditelluride (WTe₂), platinum disulfide (PtS₂), platinum diselenide (PtSe₂), platinum ditelluride (PtTe₂), erbium disulfide (ErS₂), erbium diselenide (ErSe₂), erbium ditelluride (ErTe₂), rhodium disulfide (RhS₂), rhodium diselenide (RhSe₂), rhodium ditelluride (RhTe₂), lanthanum disulfide (LaS₂), lanthanum diselenide (LaSe₂), lanthanum ditelluride (LaTe₂), niobium disulfide (NbS₂), niobium diselenide (NbSe₂), niobium ditelluride, or another disulfide, diselenide, or ditelluride TMD. In some embodiments, the TMD monolayer comprises a TMD alloy of the form ABX₂ where A and B are transition metals and X is a chalcogen. Thus, in some embodiments, the TMD monolayer can be, for example, Mo₍₁₋ₓ₎WₓS₂, Mo₍₁₋ₓ₎WₓSe₂, or W₍₁₋ₓ₎NbₓS₂. In an illustrative scenario according to one embodiment, semiconductor layer 216 comprise one or more monolayers (e.g., less than eight monolayers) of one of MoS₂, WS₂, MoSe₂, WSe₂, MoTe₂—e.g., wherein a given one such monolayer is formed by a metal-organic chemical vapor deposition (MOCVD) process.

Referring again to FIG. 1, method 100 further comprises (at 114) coupling the first material stack, which is formed at 112, to a target substrate structure. The coupling at 114 forms a second material stack which comprises the first material stack and the target substrate structure. In some embodiments, the first material stack is coupled to the first target substrate structure via a first protective layer. In this particular context, “protective” refers herein to a material or layer which provides structural and/or mask protection. In some embodiments, a material of a protection layer is further to function as a sacrificial material which is subject to being at least partially etched or otherwise removed during later fabrication processes.

For example, referring to the stage 202 shown in FIG. 2C, a protective layer 218 is formed on semiconductor layer 216 by any of various suitable deposition processes (e.g., including a blanket deposition). In an embodiment, protective layer 218 comprises any of various insulator materials (e.g., including an oxide) which are suitable, as a sacrificial material, for etching and/or other subtractive processing during later fabrication operations. By way of illustration and not limitation, protective layer 218 comprises silicon oxide (SiO₂), aluminum oxide (Al₂O₃) and/or any of various other suitable oxide materials. Alternatively or in addition, protective layer 218 comprises any of various suitable nitrides, such as titanium nitride (TiN), silicon carbide (SiC), or the like. In one embodiment, protective layer 218 comprises silicon oxycarbon nitride (SiOCN), for example. In one embodiment, a vertical (z-axis) thickness of protective layer 218 is in a range of 5 nm to 50 nm. However, protective layer 218 has a different vertical thickness in other embodiments, e.g., depending upon the design of a transistor structure which is to be formed from some or all of the material stack shown.

At the stage 203 shown in FIG. 2D, an assembly 250 (comprising growth substrate 210, release layer 212, growth layer 214, semiconductor layer 216, and protective layer 218) is inverted and adhered or otherwise bonded to a target substrate 220. Target substrate 220 illustrates any of various suitable target structures which provide structural support for semiconductor layer 216 and, in some embodiments, one or more other semiconductor layers which are to be subsequently transferred thereon. In an embodiment, target substrate 220 comprises one or more material layers in which, and/or on which, front end-of-line (FEOL) structures have been fabricated (or are to be fabricated). By way of illustration and not limitation, target substrate 220 comprises a substrate of a bulk silicon material. In one such embodiment, target substrate 220 comprises a silicon on insulator (SOI) structure that, in some embodiments, extends to a top surface of target substrate 220.

In an embodiment, a material at the top surface of the target substrate 220 is different than that of the growth layer 214. For example, a surface material of the target substrate 220 is relatively poor for promoting growth of a TMD material of the semiconductor layer 216. For example, a top surface of target substrate 220 is formed by one or more types of crystal structure which are incompatible with the growth of a particular type of TMD structure. In an embodiment, the target substrate 220 is some or all of a wafer, in which, or on which, transistor structures are two subsequently be formed.

In the example embodiment shown, the material stack which is coupled to the target substrate 220 comprises the protective layer 218—e.g., wherein protective layer 218 is adjacent to semiconductor layer 216. In such an embodiment, coupling the material stack to the target substrate 220 comprises coupling the material stack to the target substrate 220 via the protective layer 218—i.e., after the protective layer 218 has been formed on the semiconductor layer 216. In an alternative embodiment, the material stack which is coupled to target substrate 220 does not include protective layer 218—e.g., wherein coupling the material stack to the target substrate 220 comprises forming the protective layer 218 on the target substrate 220 and, subsequently, coupling the material stack to the protective layer 218 via the semiconductor layer 216. In still another embodiment, the semiconductor layer 216 (while coupled to growth substrate 210, release layer 212, and growth layer 214) is coupled directly to the target substrate 220—e.g., wherein the resulting material stack omits the protective layer 218.

Referring again to FIG. 1, method 100 further comprises (at 116) separating the growth substrate from the semiconductor layer to form a third material stack. For example, separating the growth substrate comprises performing an ablation of the release layer with a beam of laser light which is directed through the growth substrate. In an embodiment, a wavelength of the laser light is in an IR range. After the third material stack is created, the semiconductor layer forms a first surface and a second surface on opposite respective sides of the semiconductor layer. The target substrate structure is coupled to the semiconductor layer via the first surface, wherein the second surface has disposed thereon a residue of one of the release layer or the growth layer.

For example, referring now to FIG. 2E, a material stack is formed at stage 204 by the coupling of assembly 250 to target substrate 220. Subsequently, at the stage 205 shown in FIG. 2F, an ablation process is performed by directing a beam 213, from a laser device 211, through growth substrate 210 and onto a portion of the release layer 212. The beam 213 is variously moved, relative to the material stack, to ablate some or all of release layer 212 from between the growth substrate 210 and the growth layer 214.

As illustrated by the stage 206 shown in FIG. 2G, the laser ablation of release layer 212 enables growth substrate 210 to be separated from the semiconductor layer 216 (as well as from the protective layer 218 and the target substrate 220). In some embodiments, such ablation further facilitates removal of some or all of growth layer 214—e.g., wherein a heat of release layer 212, due to the beam 213, facilitates a decomposition (such as a change of phase) of at least some of growth layer 214. Additionally or alternatively, a wet each and or other suitable subtractive process is performed, after the laser ablation, to remove at least some remaining portion of the growth layer 214 from the semiconductor layer 216. In other embodiments, any remaining portion of growth layer 214 is kept on the semiconductor layer 216 after the laser ablation of release layer 212.

At stage 206, surfaces 215, 217 are formed by the semiconductor layer 216 at opposite respective sides thereof, wherein the semiconductor layer 216 is coupled to target substrate 220, directly or indirectly, via the surface 217. The protective layer 218 is between the semiconductor layer 216 and target substrate 220—e.g., wherein surface 217 is at an interface between the semiconductor layer 216 and the protective layer 218.

In various embodiments, a residue 260 adjoins the surface 215 which faces away from the target substrate 220. Residue 260 is an artefact of a layer transfer process whereby the semiconductor layer 216 is transferred onto target substrate 220. In an embodiment, the residue 260 comprises a crystalline material which is a remaining portion of growth layer 214. Alternatively or in addition, residue 260 comprises an IR absorbent material (e.g., a metal nitride) which is a remaining portion of release layer 212. In one such embodiment, the residue 260 comprises one of silicon (Si), aluminum (Al), tungsten (W), copper (Cu), titanium (Ti), tantalum (Ta), niobium (Nb), oxygen (O), nitrogen (N), hydrogen (H), or carbon (C).

In various embodiments, the residue 260 comprises an admixture of a material of growth layer 214 and constituent atoms of the TMD material of semiconductor layer 216—e.g., wherein some or all of residue 260 is an artefact of MOCVD processing which forms the TMD material on the growth layer 214. In some embodiments, residue 260 additionally or alternatively comprises a material, such any of various suitable salts, which serve as a growth promoter for growing the TMD material of semiconductor layer 216. By way of illustration and not limitation, residue 260 comprises sodium, chloride, ammonia (NH₄) and/or any of various other constituents of a growth promoter material.

In some embodiments, the residue 260 only partially covers the surface 215 of semiconductor layer 216 which faces away from target substrate 220—e.g., where other portions of surface 215 remain exposed. Due to a layer transfer process which is used to form the material stack at stage 206, an amount of the material of residue 260 at the surface 215 is greater than an amount of that same residue material (if any) at the surface 217 which is relatively close to target substrate 220. For example the material stack omits any such residue material at the surface 217, in some embodiments.

Although some embodiments are not limited in this regard, method 100 further comprises (at 118) forming structures of a transistor from the third material stack. For example, the forming at 118 comprise patterning a channel structure of the transistor from the semiconductor layer. In an illustrative scenario according to one embodiment, the material stack which is on the target substrate 220 at stage 206 is available to be subjected to additional processes that (for example) fabricate a transistor structure in or on the target substrate 220. By way of illustration and not limitation, the transistor structure comprises a channel structure which includes the same TMD material as the semiconductor layer 216—e.g., wherein a vertical thickness of the channel structure is substantially equal to a vertical thickness of the semiconductor layer 216. In one such embodiment, a vertical distance of the channel structure from the target substrate 220 is substantially equal to a vertical distance of the first semiconductor layer from the target substrate 220.

In some embodiments, method 100 further comprises one or more instances of other operations-similar to the receiving at 110, the disposing at 112, the coupling at 114, and the separating at 116—which facilitate the fabrication of a material stack comprising two or more semiconductor layers and multiple protective layers which are interleaved with the two or more semiconductor layers.

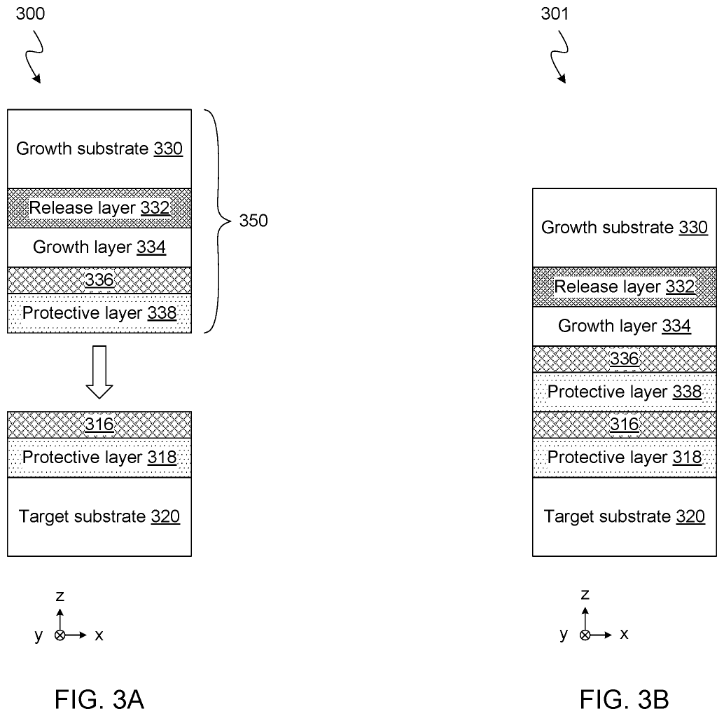

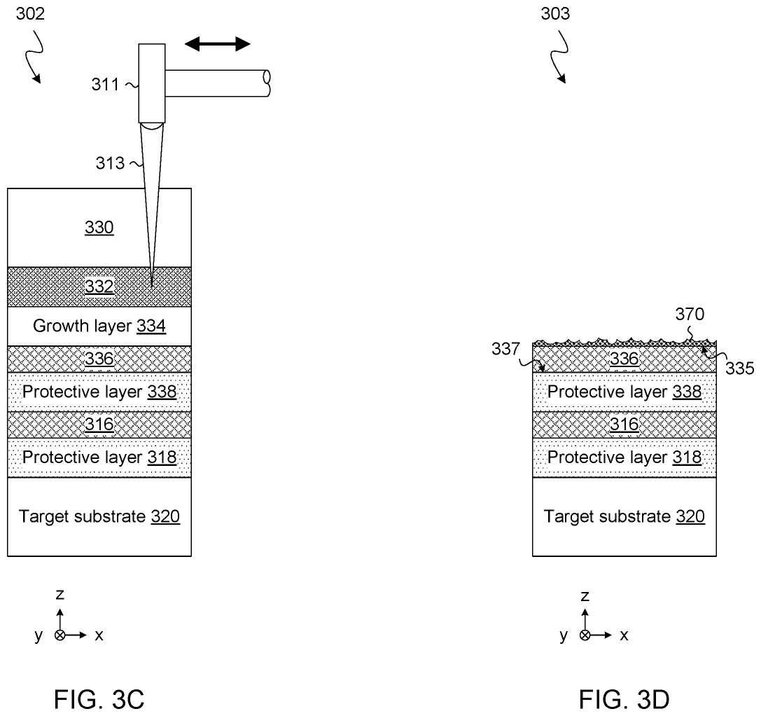

By way of illustration and not limitation, FIGS. 3A-3D show various cross-sectional side views of structures each during a respective one of multiple stages 300 through 303 of processing for providing multiple 2D material layers on a target substrate according to an embodiment. The stages 300 through 303 illustrates one embodiment which forms a material stack that, for example, can be used in the fabrication of a multi-channel (e.g., multi-nanowire, multi-nanoribbon, or the like) transistor.

At the stage 300 shown in FIG. 3A, an assembly 350 is inverted and/or otherwise positioned to be bonded to a first material stack which is already on a target substrate 320. Target substrate 320 has some or all of the features of target substrate 220, for example. The first material stack which is already on target substrate 320 at stage 300 comprises a protective layer 318 and a semiconductor layer 316 thereon—e.g., wherein semiconductor layer 316 and protective layer 318 and are semiconductor layer 216 and protective layer 218 (respectively). In one such embodiment, a residue (not shown), such as residue 260, is disposed on top of semiconductor layer 316—e.g., wherein the residue is an artefact of a layer transfer process as described herein.

The assembly 350 comprises a growth substrate 330, release layer 332, growth layer 334, semiconductor layer 336, and a protective layer 338—e.g., corresponding functionally to growth substrate 210, release layer 212, growth layer 214, semiconductor layer 216, and semiconductor layer 216 (respectively). In one such embodiment, method 100 further comprises operations to fabricate assembly 350—e.g., by growing or otherwise disposing semiconductor layer 336 on a workpiece which comprises growth substrate 330, growth layer 334, and release layer 332 between the growth substrate 330 and the growth layer 334. After the growth of semiconductor layer 336 (which comprises one or more monolayers of a TMD material), an oxide or other suitable insulator material is deposited on semiconductor layer 336 to form protective layer 338.

As illustrated in FIG. 3B, a second material stack is formed at stage 301 by the coupling of assembly 350 to the first material stack on target substrate 220. Subsequently, at the stage 302 shown in FIG. 3C, an ablation process is performed by directing a beam 313, from a laser device 311, through growth substrate 330 and onto a portion of the release layer 332. The beam 313 is variously moved, relative to the material stack, to ablate some or all of release layer 332 from between the growth substrate 330 and the growth layer 334.

As illustrated by the stage 303 shown in FIG. 3D, the laser ablation of release layer 332 enables growth substrate 330 to be separated from the semiconductor layer 336 (as well as from the protective layer 338 and first material stack which is on the target substrate 320). In some embodiments, such ablation further facilitates removal of some or all of growth layer 334. In other embodiments, a remaining portion of growth layer 334 is kept on the semiconductor layer 336 after the laser ablation of release layer 332 (or said remaining portion is removed by a wet etch process, for example).

In some embodiments, one or more additional channel structures—each comprising a respective one or more TMD monolayers—can be variously grown, each on a respective growth substrate, and transferred to the target substrate 320 to fabricate a material stack comprising more than the two semiconductor layers 316, 336 illustrated in FIG. 3D. In some embodiments, a material stack comprises five or more such channel structures, each comprising one or more TMD monolayers.

At stage 303, surfaces 335, 337 are formed by the semiconductor layer 336 at opposite respective sides thereof, wherein the semiconductor layer 336 is coupled to the first material stack (and target substrate 320) via the surface 337. The protective layer 338 is between the semiconductor layer 336 and the first material stack—e.g., wherein surface 337 is at an interface between the semiconductor layer 336 and the protective layer 338.

In various embodiments, a residue 370 adjoins the surface 335 which faces away from the target substrate 320. Residue 370 is an artefact of a layer transfer process whereby the semiconductor layer 336 is transferred onto target substrate 320. In an embodiment, the residue 370 comprises a crystalline material which is a remaining portion of growth layer 334. Alternatively or in addition, residue 370 comprises an laser absorbent material (e.g., a metal nitride) which is a remaining portion of release layer 332. In one such embodiment, the residue 370 comprises one of silicon (Si), aluminum (Al), tungsten (W), copper (Cu), titanium (Ti), tantalum (Ta), niobium (Nb), oxygen (O), nitrogen (N), hydrogen (H), or carbon (C). In various embodiments, residue 370 comprises silicon (Si), or aluminum (Al) and oxygen (O). In one embodiment, residue 370 comprises nitrogen and one of titanium, niobium, or tantalum. In some embodiments, the residue 370 comprises an admixture of a material of growth layer 334 and constituent atoms of the TMD material of semiconductor layer 336, and/or comprises a material, such any of various suitable salts, which serve as a growth promoter for growing the TMD material of semiconductor layer 336.

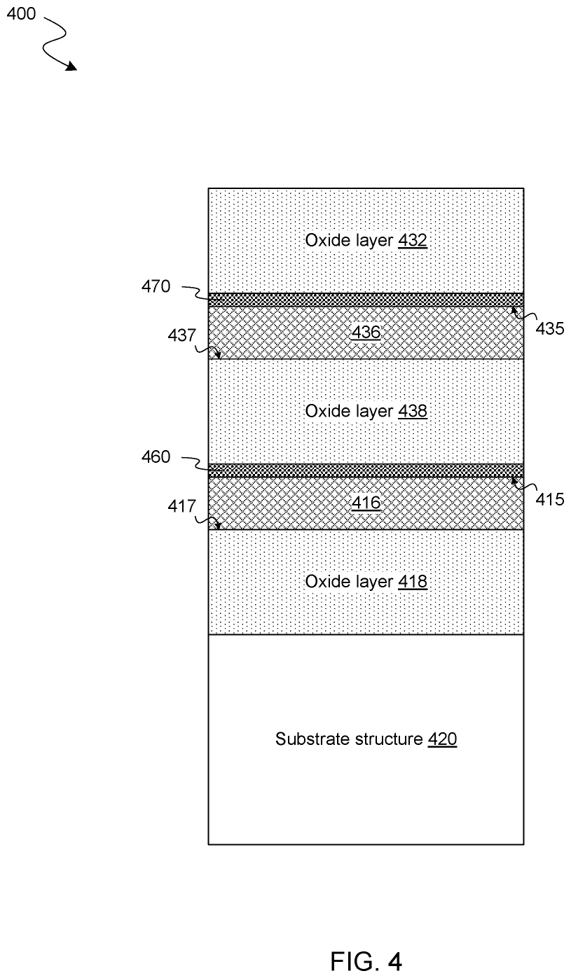

FIG. 4 shows a cross-sectional side view of an integrated circuit (IC) die 400 which comprises an artefact of a layer transfer process according to an embodiment. IC die 400 illustrates features of one example embodiment wherein multiple semiconductor layers—each comprising one or more monolayers of a respective TMD material—are interleaved with protective layers (e.g., comprising layers of a sacrificial material) to form a material stack. For each of the multiple semiconductor layers, a respective residue material is disposed on a top surface of that semiconductor layer, wherein the residue material includes comprises a material such as that of a growth layer, and/or a material such as that of a photonic release layer. In some embodiments, IC die 400 includes features shown at one of stages 206, 303—e.g., wherein operations of method 100 provide some or all structures of IC die 400.

As shown in FIG. 4, IC die 400 comprises a substrate structure 420, and a material stack which is formed on substrate structure 420. For example, the material stack is formed on substrate structure 420 using fabrication processes such as those illustrated by stages 200 through 206 or stages 300 through 303. By way of illustration and not limitation, a semiconductor layer 416 of the material stack comprises one or more monolayers of a first TMD material.

Surfaces 415, 417 are formed by the semiconductor layer 416 at opposite respective sides thereof, wherein the semiconductor layer 416 is coupled to substrate structure 420, directly or indirectly, via the surface 417. In one such embodiment, a layer 418 of the material stack comprises an oxide material (or any of various other suitable insulator materials) which is to provide structural and/or mask protection and, for example, is to function as a sacrificial material during fabrication of one or more transistor structures. The oxide layer 418 is between the semiconductor layer 416 and substrate structure 420—e.g., wherein surface 417 is at an interface between the semiconductor layer 416 and the oxide layer 418. In another embodiment, the material stack omits the oxide layer 418—e.g., wherein the semiconductor layer 416 is disposed directly on substrate structure 420 (e.g., directly on a silicon on insulator portion of substrate structure 420).

In some embodiments, the material stack further comprises another layer 438 which includes another oxide material (for example, the same material as that of oxide layer 418) which is to similarly provide structural and/or mask protection and, for example, is to function as a sacrificial material during fabrication of one or more transistor structures. The oxide layer 438 is coupled to the semiconductor layer 416 via the surface 415—e.g., wherein a residue 460 is between, and adjoins each of, the surface 415 and the oxide layer 438

In various embodiments, residue 460 is an artefact of a layer transfer process whereby a portion of the material stack is disposed on the substrate structure 420. In an embodiment, the residue 460 comprises a crystalline material which, for example, is a remaining portion of growth layer 214. In one such embodiment, the crystalline material comprises one of a silicon material or a sapphire material. Alternatively or in addition, residue 460 comprises a metal nitride which, for example, is a remaining portion of release layer 212. The metal nitride (or any of various other suitable photonic release materials) is absorbent of a laser light—e.g., wherein wavelength of the laser light is in an infrared range. In one such embodiment, the residue 460 comprises nitrogen and one of titanium, niobium, or tantalum.

In various embodiments, the residue 460 comprises the crystalline material and a constituent of the TMD material of semiconductor layer 416—e.g., wherein some or all of residue 460 is an artefact of MOCVD processing which forms the TMD material on a growth layer. In some embodiments, residue 460 additionally or alternatively comprises a material, such any of various suitable salts, which serve as a growth promoter for growing the TMD material of semiconductor layer 416. By way of illustration and not limitation, residue 460 comprises sodium, chloride, ammonia (NH₄) and/or any of various other constituents of a growth promoter material.

The material stack further comprises another semiconductor layer 436 comprising one or more monolayers of another TMD material (for example, the same as that of semiconductor layer 416). The semiconductor layer 436 forms surfaces 435, 437 one opposite respective sides thereof—e.g., wherein the semiconductor layer 436 is coupled to the oxide layer 438 via the surface 437. By way of illustration and not limitation, substrate structure 420, oxide layer 418, semiconductor layer 416, oxide layer 438, and semiconductor layer 436 correspond functionally to target substrate 320, protective layer 318, semiconductor layer 316, protective layer 338, and semiconductor layer 336 (respectively).

In an embodiment, a layer 432 of another oxide material (e.g., such as that of one of oxide layers 418, 438) is coupled to the semiconductor layer 436 via the surface 435. Oxide layer 432 provides structural and/or mask protection and, for example, is to function as a sacrificial material during fabrication of one or more transistor structures. In one such embodiment, the material stack further comprises a residue 470 which is between, and adjoins each of, the surface 435 and the oxide layer 432. Similar to the residue 460, residue 470 is an artefact of a layer transfer process whereby another portion of the material stack is disposed on the portion which comprises semiconductor layer 416. For example, the residue 470 comprises a crystalline material which, for example, is a remaining portion of growth layer 334. Alternatively or in addition, residue 470 comprises a metal nitride (or any of various other suitable photonic release materials) which, for example, is a remaining portion of release layer 332. In various embodiments, the residue 470 includes one or more other features of residue 460.

It is to be appreciated that, in some embodiments, residue 460 only partially separates the semiconductor layer 416 from oxide layer 438—e.g., wherein some portions of the oxide layer 438 are directly in contact with the surface 415 of semiconductor layer 416. Alternatively or in addition, the residue 470 only partially separates the semiconductor layer 436 from oxide layer 432, in some embodiments. Due to a layer transfer process which is used to form the material stack, an amount of the material of residue 460 at the surface 415 is greater than an amount of that same residue material (if any) at the surface 417 which is relatively close to substrate structure 420. Alternatively or in addition, an amount of the material of residue 470 at the surface 435 is greater than an amount of that same residue material (if any) at the surface 437 which is relatively close to substrate structure 420.

In various embodiments, the material stack is a remnant of a larger material stack which was subjected to additional fabrication processing to form one or more transistors (not shown) of IC die 400. In an embodiment, a given one such transistor comprises a first channel structure which is formed from a larger semiconductor layer, of which the smaller semiconductor layer 416 is a remnant. As a result, the first channel structure comprises the same TMD material as that of semiconductor layer 416—e.g., wherein a vertical thickness of the first channel structure is substantially equal to a vertical thickness of the semiconductor layer 416. Alternatively or in addition, a vertical distance of the first channel structure from substrate structure 420 is substantially equal to a vertical distance of the semiconductor layer 416 from substrate structure 420

Alternatively or in addition, the given transistor comprises a second channel structure which is formed from a larger semiconductor layer, of which the smaller semiconductor layer 436 is a remnant. As a result, the second channel structure comprises the same TMD material as that of semiconductor layer 436—e.g., wherein a vertical thickness of the second channel structure is substantially equal to a vertical thickness of the semiconductor layer 436. Alternatively or in addition, a vertical distance of the second channel structure from substrate structure 420 is substantially equal to a vertical distance of the semiconductor layer 436 from substrate structure 420.

In some embodiments, one or more additional channel structures—each comprising a respective one or more TMD monolayers—can be variously grown, each on a respective growth substrate, and transferred to the substrate structure 420 to fabricate a material stack comprising more than the two semiconductor layers 416, 436 illustrated in FIG. 4. In some embodiments, a material stack comprises five or more such channel structures, each comprising one or more TMD monolayers.

In various embodiments, the material stack on substrate structure 420 is remnant of transistor fabrication, and is located in a region of IC die 400 which is outside of (e.g., between, or in a periphery around) any device region(s) where transistor structures are variously formed in and/or on substrate structure 420. In one such embodiment, the material stack only partially covers the substrate structure 420, which further extends horizontally into one such device region. By way of illustration and not limitation, the material stack is in a buffer region of the IC die 400—e.g., near a chip scribe structure which is a remnant of a cutting (or other) process that singulates the IC die 400 from a wafer.

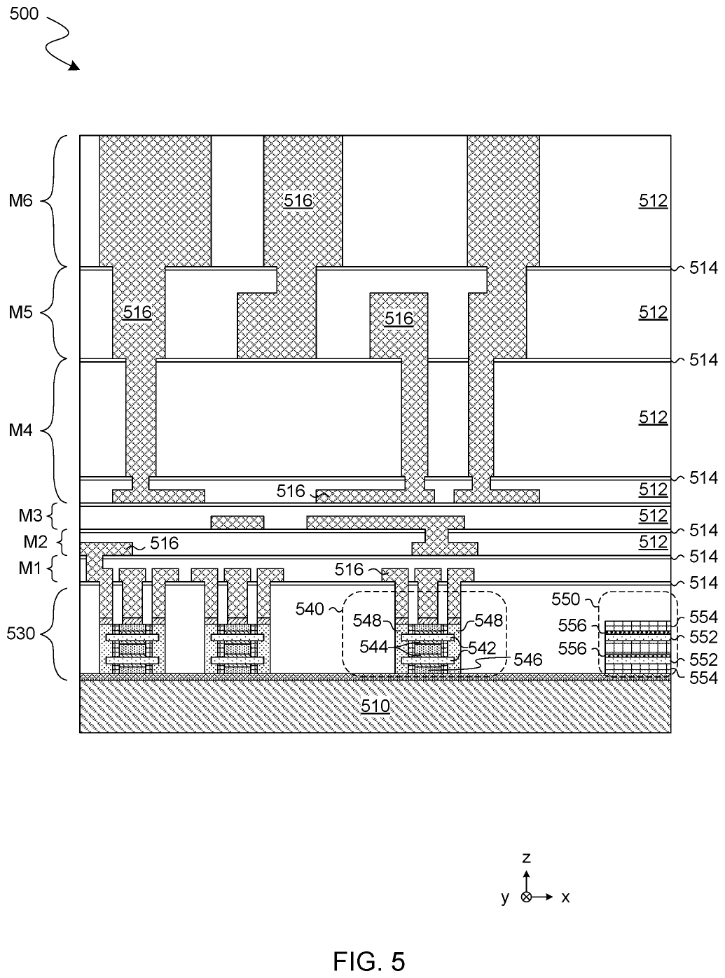

FIG. 5 illustrates a cross-sectional side view of an integrated circuit (IC) device 500 which comprises an artefact of a 2D layer transfer process in accordance with some embodiments. IC device 500 illustrates a portion of a monolithic IC that includes front end of line (FEOL) circuit structures that are over and/or on a monocrystalline substrate 510. IC device 500 further includes back end of line (BEOL) circuit structures that are over and/or on the FEOL circuit structures. In an illustrative scenario according to one embodiment, the FEOL circuit structures comprise a transistor structure 540 which (for example) includes one or more channel structures formed from a 2D material which is subjected to a layer transfer process.

In the illustrated example, FEOL circuit structures include a plurality of field effect transistors (FETs) 530, one or more of which—such as the illustrative transistor structure 540 shown—employ a respective one or more TMD layer structures each for at least a respective channel region of the transistor. Although some embodiments are not limited in this regard, the FEOL circuit structures further include any of various other types of transistors (e.g., bipolar junction transistor, etc.), and/or other active devices employing one or more semiconductor materials (e.g., diodes, lasers, etc.).

In the example embodiment shown, transistor structure 540 comprises a vertically arranged plurality of channel structures 542—e.g., comprising nanowires, nanoribbons, or the like—which (for example) each comprise a respective TMD layer, such as a 2D material structure. By way of illustration and not limitation, the channel structures 542 variously extend between, and to each of, two source or drain (S/D) electrode structures 548 of transistor structure 540. A gate electrode structure 546 of transistor structure 540 is disposed between the S/D electrode structures 548, wherein gate electrode structure 546 variously extends around each of channel structures 542. In an embodiment, gate dielectric structures 544 of transistor structure 540 each surround a different respective one of channel structures 542, to facilitate at least partial electrical insulation of the channel structures 542 from gate electrode structure 546. In one such embodiment, spacer structures of transistor structure 540 are variously disposed each between gate electrode structure 546 and a different respective one of S/D electrode structures 548—e.g., wherein channel structures 542 variously extend through the spacer structures to the S/D electrode structures 548. For example, the spacer structures comprise any of various suitable dielectric materials to provide electrical insulation between gate electrode structure 546 and the S/D electrode structures 548.

During operation of device 500, transistor structure 540 is operated, based on a voltage which is provided at gate electrode structure 546, to selectively control an amount of current which is conducted between S/D electrode structures 548 via channel structures 542. For example, the gate electrode structure 546 and the S/D electrode structures 548 are variously coupled (directly or indirectly) each to a respective one of interconnect metallization features 516—e.g., to facilitate operation of transistor structure 540 and/or signal communication with any of various other suitable circuit components which IC device 500 includes, or is to be coupled to.

In various embodiments, IC device 500 further comprises a stack of multiple material layers—such as the illustrative material stack 550 shown—which is an artefact of a layer transfer process as described herein. In one such embodiment, material stack 550 is located outside of a region where patterning, etching and/or other processes have formed some or all of FEOL transistors 530 on substrate 510. By way of illustration and not limitation, material stack 550 is between two such regions or (for example) is in a buffer region which includes and/or extends vertically over a side of substrate 510—where scribing is performed in or along the buffer region to singulate IC die from a wafer.

In an embodiment, channel structures 542 are each formed by fabrication processes which pattern and/or otherwise remove material from a larger stack, of which material stack 550 is a remaining portion. For example, prior to the fabrication operations, such a larger stack comprises larger stacked semiconductor layers which are patterned to form channel structures 542, wherein semiconductor layers 552 of material stack 550 are another remnant of the larger stacked semiconductor layers.

In some embodiments, the larger stack further comprises one or more sacrificial layers which (for example) are interleaved with the larger stacked semiconductor layers. For example, patterning of the larger stacked semiconductor layers further includes, or is performed in combination with, an etching and/or other subtractive processing to remove portions of the one or more sacrificial layers. In one such embodiment, oxide layers 554 of transistor structure 540 are a remnant of such one or more sacrificial layers, wherein transistor structure 540 are interleaved with semiconductor layers 552.

In some embodiments, formation of the larger stack comprises one or more 2D layer transfer processes as described herein. In one such embodiment, material stack 550 further comprises residual portions 556 which are variously disposed each between a different respective one of semiconductor layers 552 and a different respective one of oxide layers 554. By way of illustration and not limitation, semiconductor layers 552 correspond to semiconductor layers 416, 436—e.g., wherein oxide layers 554 correspond to oxide layers 418, 438, 432 and (for example) wherein residual portions 556 correspond to residue 440, and residue 450

In an embodiment, the FEOL circuit structures include one or more levels of interconnect metallization features 516 electrically insulated by dielectric materials 512 and 514. In the exemplary embodiment illustrated, the FEOL circuit structures include metal-one (M1), metal-two (M2), and metal-three (M3) interconnect metallization levels. Interconnect metallization features 516 are of any metal(s) suitable for FEOL and/or BEOL IC interconnection. Dielectric material 514 may have a different composition that dielectric material 512, and may be of a composition that has a higher dielectric constant than that of dielectric material 512. In some examples wherein dielectric material 512 is predominantly silicon and oxygen (i.e., SiOₓ), dielectric material 514 is predominantly silicon and nitrogen (i.e., SiNₓ). In other examples, where dielectric material 512 is a low-k dielectric (e.g., carbon-doped silicon oxide, SiOC:H), dielectric material 514 is predominantly a higher-k dielectric (e.g., SiO₂).

As further illustrated in FIG. 5, the BEOL circuit structures may further comprise any number of metallization levels, such as a metallization level (e.g., M5 and M6) above the metallization level (e.g., M4). Any number of interconnect metallization levels may couple BEOL circuitry 560 to the underlying the FEOL circuit structures. In the example shown in FIG. 5, metallization levels of BEOL circuitry (e.g., M6) may be routed down through any number of metallization levels (e.g., M5-M3) to be in electrical communication with one or more FEOL transistors 530.

In further embodiments, there may be multiple levels of the BEOL circuit structures located over the FEOL circuit structures, with dielectric material between each BEOL device circuitry level. A level of the BEOL circuit structures may include a plurality of PMOS and/or NMOS transistor structures, for example. In other embodiments, an IC structure includes multiple levels of the BEOL circuit structures without any monocrystalline FEOL transistors. For such embodiments, one or more levels of transistor structures may be over any of various suitable substrates (e.g., polymer, glass, etc.).

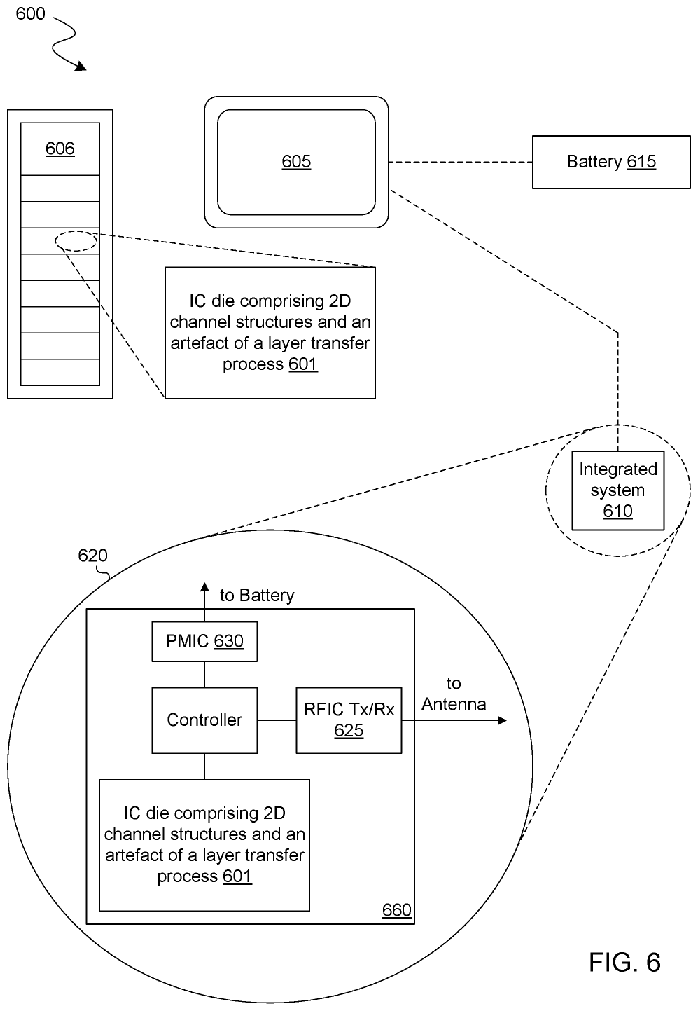

FIG. 6 illustrates a system 600 comprising a mobile computing platform 605 and a data server machine 606 employing a packaged IC die which include one or more metal chalcogenide transistors having respective partially metallized layer structures, for example as described elsewhere herein. Server machine 606 may be any commercial server, for example including any number of high-performance computing platforms disposed within a rack and networked together for electronic data processing, which in the exemplary embodiment includes a packaged IC die comprising IC structure 601, for example as described elsewhere herein.

The mobile computing platform 605 may be any portable device configured for each of electronic data display, electronic data processing, wireless electronic data transmission, or the like. For example, the mobile computing platform 605 may be any of a tablet, a smart phone, laptop computer, etc., and may include a display screen (e.g., a capacitive, inductive, resistive, or optical touchscreen), an integrated system 610, and a battery 615.

As illustrated in the expanded view 620, another IC structure 601 is additionally or alternatively coupled to host component 660. One or more of a power management integrated circuit (PMIC) 630 or RF (wireless) integrated circuit (RFIC) 625 including a wideband RF (wireless) transmitter and/or receiver may be further coupled to host component 660. PMIC 630 may perform battery power regulation, DC-to-DC conversion, etc., and so has an input coupled to battery 615 and with an output providing a current supply to other functional modules. As further illustrated, in the exemplary embodiment, RFIC 625 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G and beyond.

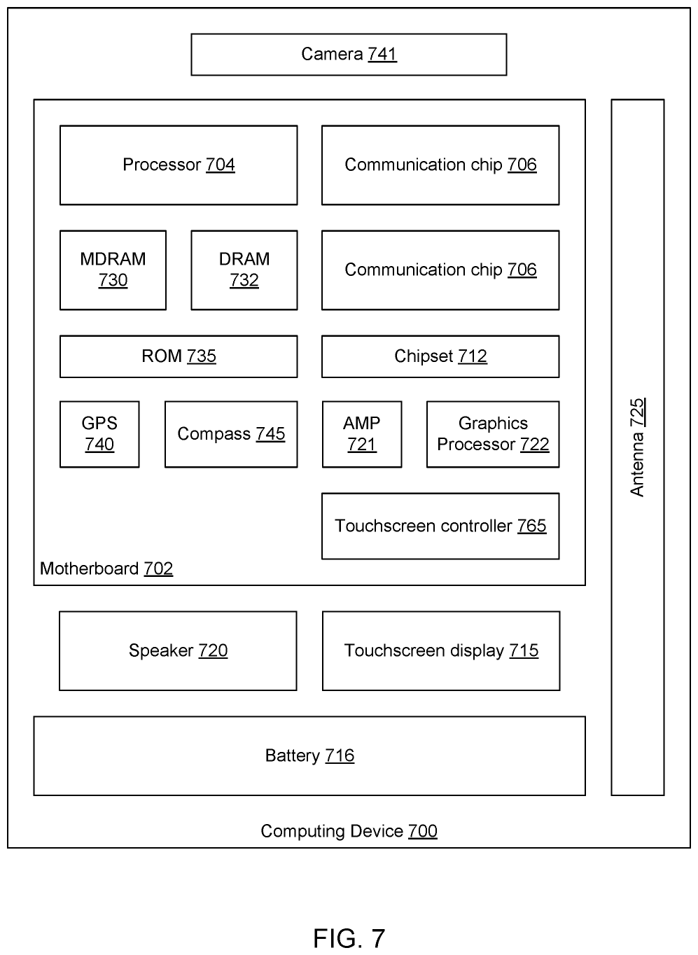

FIG. 7 is a functional block diagram of an electronic computing device 700, in accordance with some embodiments. Device 700 includes circuit structures which include an artefact of a layer transfer process according to an embodiment. For example, device 700 includes a motherboard 702 hosting a number of components, such as, but not limited to, a processor 704 (e.g., an applications processor). Processor 704 may be physically and/or electrically coupled to motherboard 702. In some examples, processor 704 is part of a monolithic 3DIC structure, for example as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 706 may also be physically and/or electrically coupled to the motherboard 702. In further implementations, communication chips 706 may be part of processor 704. Depending on its applications, computing device 700 may include other components that may or may not be physically and electrically coupled to motherboard 702. These other components include, but are not limited to, volatile memory (e.g., DRAM 732), non-volatile memory (e.g., ROM 735), flash memory (e.g., NAND or NOR), magnetic memory (MRAM) 730, a graphics processor 722, a digital signal processor, a crypto processor, a chipset 712, an antenna 725, touchscreen display 715, touchscreen controller 765, battery 716, audio codec, video codec, power amplifier (AMP) 721, global positioning system (GPS) device 740, compass 745, accelerometer, gyroscope, speaker 720, camera 741, and mass storage device (such as hard disk drive, solid-state drive (SSD), compact disk (CD), digital versatile disk (DVD), and so forth, or the like.

Communication chips 706 may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 706 may implement any of a number of wireless standards or protocols, including, but not limited to, those described elsewhere herein. As discussed, computing device 700 may include a plurality of communication chips 706. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

The description herein sets forth numerous details to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a.” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially.” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “left,” “right,” “front.” “back.” “top.” “bottom,” “over,” “under,” and the like in the description and in the claims, if any, are used for descriptive purposes and not necessarily for describing permanent relative positions. For example, the terms “over,” “under,” “front side,” “back side,” “top.” “bottom,” “over.” “under.” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

Techniques and architectures for providing integrated circuit structures are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

In one or more first embodiments, an integrated circuit (IC) die comprises a substrate structure, and a material stack comprising a first semiconductor layer comprising one or more monolayers of a first transition metal dichalcogenide (TMD) material, wherein a first surface and a second surface are formed by opposite respective sides of the first semiconductor layer, wherein the first semiconductor layer is coupled to the substrate structure via the first surface, a first protective layer coupled to the first semiconductor layer via the second surface, and a first residue which is between, and adjoins each of the second surface and the first protective layer, wherein the first residue comprises one of a crystalline material or a first material which is absorbent of a laser light, wherein wavelength of the laser light is in an infrared range.

In one or more second embodiments, further to the first embodiment, the first residue comprises the crystalline material and a constituent of the first TMD material.

In one or more third embodiments, further to the first embodiment or the second embodiment, the first residue comprises the crystalline material, and the crystalline material comprises one of a silicon material or a sapphire material.

In one or more fourth embodiments, further to any of the first through third embodiments, the first residue comprises one of silicon, aluminum, tungsten, copper, titanium, tantalum, niobium, oxygen, nitrogen, hydrogen, or carbon.

In one or more fifth embodiments, further to any of the first through fourth embodiments, the material stack further comprises a second semiconductor layer comprising one or more monolayers of a second TMD material, wherein a third surface and a fourth surface are formed by opposite respective sides of the second semiconductor layer, wherein the second semiconductor layer is coupled to the first protective layer via the third surface, a second protective layer coupled to the second semiconductor layer via the fourth surface, and a second residue which is between, and adjoins each of the fourth surface and the second protective layer, wherein the second residue comprises one of a second crystalline material or a second material which is absorbent of the laser light.

In one or more sixth embodiments, further to any of the first through fifth embodiments, the IC die further comprises a transistor structure on the substrate structure, wherein the transistor structure comprises a channel structure comprising the first TMD material, wherein a vertical thickness of the channel structure is substantially equal to a vertical thickness of the first semiconductor layer.

In one or more seventh embodiments, further to the sixth embodiment, a vertical distance of the channel structure from the substrate structure is substantially equal to a vertical distance of the first semiconductor layer from the substrate structure.

In one or more eighth embodiments, further to any of the first through fifth embodiments, the material stack is in a buffer region of the IC die.

In one or more ninth embodiments, further to any of the first through fifth embodiments, an amount of the first residue at the second surface is greater than an amount of the first residue at the first surface.

In one or more tenth embodiments, a circuit device comprises a substrate structure, and patterned metallization layers on the substrate structure, a material stack between the substrate structure and the patterned metallization layers, the material stack comprising a first layer comprising one or more monolayers of a first transition metal dichalcogenide (TMD) material, wherein a first surface and a second surface are formed by opposite respective sides of the first layer, wherein the first layer is coupled to the substrate structure via the first surface, a second layer of a first insulator material, the second layer coupled to the first layer via the second surface, and a first residue which is between, and adjoins each of the second surface and the second layer, wherein the first residue comprises one of a crystalline material or a first material which is absorbent of a laser light, wherein wavelength of the laser light is in an infrared range.

In one or more eleventh embodiments, further to the tenth embodiment, the first residue comprises the crystalline material and a constituent of the first TMD material.

In one or more twelfth embodiments, further to the tenth embodiment or the eleventh embodiment, the first residue comprises one of silicon, aluminum, tungsten, copper, titanium, tantalum, niobium, oxygen, nitrogen, hydrogen, or carbon.

In one or more thirteenth embodiments, further to any of the tenth through twelfth embodiments, the material stack further comprises a third layer comprising one or more monolayers of a second TMD material, wherein a third surface and a fourth surface are formed by opposite respective sides of the third layer, wherein the third layer is coupled to the second layer via the third surface, a fourth layer of a second insulator material coupled to the third layer via the fourth surface, and a second residue which is between, and adjoins each of the fourth surface and the fourth layer, wherein the second residue comprises one of a second crystalline material or a second material which is absorbent of the laser light.

In one or more fourteenth embodiments, further to any of the tenth through thirteenth embodiments, the circuit device further comprises a transistor structure on the substrate structure, wherein the transistor structure comprises a channel structure comprising the first TMD material, wherein a vertical thickness of the channel structure is substantially equal to a vertical thickness of the first layer.

In one or more fifteenth embodiments, further to the fourteenth embodiment, a vertical distance of the channel structure from the substrate structure is substantially equal to a vertical distance of the first layer from the substrate structure.

In one or more sixteenth embodiments, further to any of the tenth through thirteenth embodiments, the material stack further comprises a third layer comprising one or more monolayers of a second TMD material, wherein a third surface and a fourth surface are formed by opposite respective sides of the third layer, wherein the third layer is coupled to the second layer via the third surface, a fourth layer of a second insulator material coupled to the third layer via the fourth surface, and a second residue which is between, and adjoins each of the fourth surface and the fourth layer, wherein the second residue comprises one of a second crystalline material or a second material which is absorbent of the laser light.

In one or more seventeenth embodiments, further to the sixteenth embodiment, the circuit device further comprises a transistor structure on the substrate structure, the transistor structure comprising a first channel structure comprising the first TMD material, wherein a vertical thickness of the first channel structure is substantially equal to a vertical thickness of the first layer, and a second channel structure comprising the second TMD material, wherein a vertical thickness of the second channel structure is substantially equal to a vertical thickness of the third layer.

In one or more eighteenth embodiments, further to the seventeenth embodiment, a vertical distance of the first channel structure from the substrate structure is substantially equal to a vertical distance of the first layer from the substrate structure, and a vertical distance of the second channel structure from the substrate structure is substantially equal to a vertical distance of the third layer from the substrate structure.

In one or more nineteenth embodiments, further to any of the tenth through thirteenth embodiments, the circuit device is an integrated circuit (IC) die, and wherein the material stack is in a buffer region of the IC die.

In one or more twentieth embodiments, a method comprises receiving a first workpiece comprising a first growth substrate, a first growth layer, and a first release layer between the first growth substrate and the first growth layer, disposing a first semiconductor layer, on a surface of the first growth layer, to form a first material stack, wherein the first semiconductor layer comprises one or more monolayers of a first transition metal dichalcogenide (TMD) material, coupling the first material stack, to a first target substrate structure, to form a second material stack, and separating the first growth substrate from the first semiconductor layer to form a third material stack, wherein separating the first growth substrate comprises performing an ablation of the first release layer with a beam of laser light which is directed through the first growth substrate.

In one or more twenty-first embodiments, further to the twentieth embodiment, wherein, after the third material stack is created the first semiconductor layer forms a first surface and a second surface on opposite respective sides of the first semiconductor layer, the first target substrate structure is coupled to the first semiconductor layer via the first surface, and the third material stack comprises a residue, on the second surface, of one of the first release layer or the first growth layer.

In one or more twenty-second embodiments, further to the twentieth embodiment or the twenty-first embodiment, the first material stack is coupled to the first target substrate structure via a first protective layer to form the second material stack.

In one or more twenty-third embodiments, further to the twenty-second embodiment, the first material stack comprises the first protective layer adjacent to the first semiconductor layer, and coupling the first material stack to the first target substrate structure comprises, after the first protective layer is formed on the first semiconductor layer, coupling the first material stack to the first target substrate structure via the first protective layer.

In one or more twenty-fourth embodiments, further to the twenty-second embodiment, coupling the first material stack to the first target substrate structure comprises forming the first protective layer on the first target substrate structure, and after the first protective layer is formed on the first target substrate structure, coupling the first material stack to the first protective layer via the first semiconductor layer.

In one or more twenty-fifth embodiments, further to the twentieth embodiment or the twenty-first embodiment, the method further comprises receiving a second workpiece comprising a second growth substrate, a second growth layer, and a second release layer between the second growth substrate and the second growth layer, disposing a second semiconductor layer, on a surface of the second growth layer, to form a fourth material stack, wherein the second semiconductor layer comprises one or more monolayers of a second TMD material, coupling the fourth material stack, to the third material stack, to form a fifth material stack, and separating the second growth substrate from the second semiconductor layer to form a sixth material stack, wherein separating the second growth substrate comprises performing an ablation of the second release layer with another beam of laser light which is directed through the second growth substrate.

In one or more twenty-sixth embodiments, further to the twenty-fifth embodiment, after the sixth material stack is created the first semiconductor layer forms a first surface and a second surface on opposite respective sides of the first semiconductor layer, the first target substrate structure is coupled to the first semiconductor layer via the first surface, and the sixth material stack comprises a first residue, on the second surface, of one of the first release layer or the first growth layer.

In one or more twenty-seventh embodiments, further to the twenty-sixth embodiment, after the sixth material stack is created the second semiconductor layer comprises a third surface and a fourth surface on opposite respective sides of the second semiconductor layer, the first target substrate structure is coupled to the second semiconductor layer via the third surface, and the sixth material stack comprises a second residue, on the fourth surface, of one of the second release layer or the second growth layer.

In one or more twenty-eighth embodiments, further to the twentieth embodiment or the twenty-first embodiment, the method further comprises forming structures of a transistor from the third material stack, comprising forming a first channel structure of the transistor from the first semiconductor layer.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. An integrated circuit (IC) die comprising:
a substrate structure; and
a material stack comprising:
a first semiconductor layer comprising one or more monolayers of a first transition metal dichalcogenide (TMD) material, wherein a first surface and a second surface are formed by opposite respective sides of the first semiconductor layer, wherein the first semiconductor layer is coupled to the substrate structure via the first surface;
a first protective layer coupled to the first semiconductor layer via the second surface; and
a first residue which is between, and adjoins each of the second surface and the first protective layer, wherein the first residue comprises one of a crystalline material or a first material which is absorbent of a laser light, wherein wavelength of the laser light is in an infrared range.

2. The IC die of claim 1, wherein the first residue comprises the crystalline material and a constituent of the first TMD material.

3. The IC die of claim 1, wherein:
the first residue comprises the crystalline material; and
the crystalline material comprises one of a silicon material or a sapphire material.

4. The IC die of claim 1, wherein the first residue comprises one of silicon, aluminum, tungsten, copper, titanium, tantalum, niobium, oxygen, nitrogen, hydrogen, or carbon.

5. The IC die of claim 1, wherein the material stack further comprises:
a second semiconductor layer comprising one or more monolayers of a second TMD material, wherein a third surface and a fourth surface are formed by opposite respective sides of the second semiconductor layer, wherein the second semiconductor layer is coupled to the first protective layer via the third surface;
a second protective layer coupled to the second semiconductor layer via the fourth surface; and
a second residue which is between, and adjoins each of the fourth surface and the second protective layer, wherein the second residue comprises one of a second crystalline material or a second material which is absorbent of the laser light.

6. The IC die of claim 1, further comprising:
a transistor structure on the substrate structure, wherein the transistor structure comprises a channel structure comprising the first TMD material, wherein a vertical thickness of the channel structure is substantially equal to a vertical thickness of the first semiconductor layer.

7. The IC die of claim 6, wherein a vertical distance of the channel structure from the substrate structure is substantially equal to a vertical distance of the first semiconductor layer from the substrate structure.

8. The IC die of claim 1, wherein the material stack is in a buffer region of the IC die.

9. The IC die of claim 1, wherein an amount of the first residue at the second surface is greater than an amount of the first residue at the first surface.

10. A circuit device comprising:
a substrate structure; and
patterned metallization layers on the substrate structure;
a material stack between the substrate structure and the patterned metallization layers, the material stack comprising:
a first layer comprising one or more monolayers of a first transition metal dichalcogenide (TMD) material, wherein a first surface and a second surface are formed by opposite respective sides of the first layer, wherein the first layer is coupled to the substrate structure via the first surface;
a second layer of a first insulator material, the second layer coupled to the first layer via the second surface; and
a first residue which is between, and adjoins each of the second surface and the second layer, wherein the first residue comprises one of a crystalline material or a first material which is absorbent of a laser light, wherein wavelength of the laser light is in an infrared range.

11. The circuit device of claim 10, wherein the material stack further comprises:
a third layer comprising one or more monolayers of a second TMD material, wherein a third surface and a fourth surface are formed by opposite respective sides of the third layer, wherein the third layer is coupled to the second layer via the third surface;
a fourth layer of a second insulator material coupled to the third layer via the fourth surface; and
a second residue which is between, and adjoins each of the fourth surface and the fourth layer, wherein the second residue comprises one of a second crystalline material or a second material which is absorbent of the laser light.

12. The circuit device of claim 10, further comprising:
a transistor structure on the substrate structure, wherein the transistor structure comprises a channel structure comprising the first TMD material, wherein a vertical thickness of the channel structure is substantially equal to a vertical thickness of the first layer.

13. The circuit device of claim 12, wherein a vertical distance of the channel structure from the substrate structure is substantially equal to a vertical distance of the first layer from the substrate structure.

14. The circuit device of claim 11, further comprising a transistor structure on the substrate structure, the transistor structure comprising:
a first channel structure comprising the first TMD material, wherein a vertical thickness of the first channel structure is substantially equal to a vertical thickness of the first layer; and
a second channel structure comprising the second TMD material, wherein a vertical thickness of the second channel structure is substantially equal to a vertical thickness of the third layer.

15. The circuit device of claim 14, wherein:
a vertical distance of the first channel structure from the substrate structure is substantially equal to a vertical distance of the first layer from the substrate structure; and
a vertical distance of the second channel structure from the substrate structure is substantially equal to a vertical distance of the third layer from the substrate structure.

16. The circuit device of claim 10, wherein the circuit device is an integrated circuit (IC) die, and wherein the material stack is in a buffer region of the IC die.

17. A method comprising:
receiving a first workpiece comprising a first growth substrate, a first growth layer, and a first release layer between the first growth substrate and the first growth layer;
disposing a first semiconductor layer, on a surface of the first growth layer, to form a first material stack, wherein the first semiconductor layer comprises one or more monolayers of a first transition metal dichalcogenide (TMD) material;
coupling the first material stack, to a first target substrate structure, to form a second material stack; and
separating the first growth substrate from the first semiconductor layer to form a third material stack, wherein separating the first growth substrate comprises performing an ablation of the first release layer with a beam of laser light which is directed through the first growth substrate.

18. The method of claim 17, wherein, after the third material stack is created:
the first semiconductor layer forms a first surface and a second surface on opposite respective sides of the first semiconductor layer;
the first target substrate structure is coupled to the first semiconductor layer via the first surface; and
the third material stack comprises a residue, on the second surface, of one of the first release layer or the first growth layer.

19. The method of claim 17, further comprising:
receiving a second workpiece comprising a second growth substrate, a second growth layer, and a second release layer between the second growth substrate and the second growth layer;
disposing a second semiconductor layer, on a surface of the second growth layer, to form a fourth material stack, wherein the second semiconductor layer comprises one or more monolayers of a second TMD material;
coupling the fourth material stack, to the third material stack, to form a fifth material stack; and
separating the second growth substrate from the second semiconductor layer to form a sixth material stack, wherein separating the second growth substrate comprises performing an ablation of the second release layer with another beam of laser light which is directed through the second growth substrate.

20. The method of claim 19, wherein, after the sixth material stack is created:
the first semiconductor layer forms a first surface and a second surface on opposite respective sides of the first semiconductor layer;
the first target substrate structure is coupled to the first semiconductor layer via the first surface; and
the sixth material stack comprises a first residue, on the second surface, of one of the first release layer or the first growth layer.
